(19) United States
(12) Patent Application Publication
(10) Pub. No.: US 2013/0125391 A1
(43) Pub. Date: May 23, 2013

(54) MOUNTING APPARATUS, METHOD OF MOUNTING ELECTRONIC COMPONENT, METHOD OF MANUFACTURING SUBSTRATE, AND PROGRAM

(71) Applicant: Sony Corporation, Tokyo (JP)

(72) Inventor: Keisuke Ishida, Ibaraki (JP)

(73) Assignee: SONY CORPORATION, Tokyo (JP)

(21) Appl. No.: 13/676,787

(22) Filed: Nov. 14, 2012

(30) Foreign Application Priority Data
Nov. 21, 2011 (JP) 2011-253625

(51) Int. Cl. H05K 13/04; H05K 3/30

(52) U.S. Cl. CPC H05K 13/0404; H05K 3/301
USPC 29/832; 29/739

(57) ABSTRACT

A mounting apparatus includes a first mounting head, a second mounting head, and a controller. The first mounting head and the second mounting head are configured to each repeat a holding operation of holding an electronic component and a mounting operation of mounting the electronic component held on a substrate to alternately mount the electronic components on the substrate. The controller is configured to compare, when the first mounting head and the second mounting head complete the holding operation and are each in a state of being capable of mounting the electronic component, a first value relating to a remaining mounting time period of the first mounting head and a second value relating to a remaining mounting time period of the second mounting head, to cause the mounting operation by the mounting head corresponding to a larger value between the first value and the second value to be preferentially performed.

### BACKGROUND

The present disclosure relates to a technique of a mounting apparatus that mounts electronic components on a substrate, and the like.

From the past, there has been widely known a mounting apparatus that mounts IC (Integrated Circuit) chips and electronic components such as a resistor and a capacitor on a substrate.

As such a mounting apparatus, a mounting apparatus having two mounting heads is known (see, for example, Japanese Patent Application Laid-open Nos. HEI11-145688 and 2007-53271 (hereinafter, referred to as Patent Documents 1 and 2, respectively)). In the mounting apparatus of this type, when a first mounting head is mounting an electronic component on a substrate, a second mounting head sucks an electronic component supplied from a component supply unit. Meanwhile, when the second mounting head is mounting an electronic component on the substrate, the first mounting head sucks an electronic component supplied from the component supply unit. The first mounting head and the second mounting head repeat those operations alternately, thereby shortening a substrate production time period.

Here, the case is thought in which when one of the first mounting head and the second mounting head is mounting an electronic component on the substrate, sucking of an electronic component by the other mounting head is terminated. In this case, generally, until the mounting head that is mounting the electronic component terminates the mounting, the other mounting head stands by on such a position as not to interfere the mounting head during the mounting (see, Patent Document 2).

### SUMMARY

In general, in the mounting of an electronic component on a substrate, an optimal order of mounting is calculated among a plurality of mounting heads prior to the mounting of an electronic component, so wasted time such as a standby time period is set to be minimized.

However, in the case where a non-sucking error of an electronic component or a mounting error based on a sucking of a defective component is caused, an additional operation for correcting the error is necessary, and the mounting order is disturbed, with the result that the wasted time is generated. As a result, there arises a problem in that it takes longer time to produce one substrate.

In view of the above-mentioned circumstances, it is desirable to provide a technique of a mounting apparatus capable of suppressing an increase of a substrate production time period due to an occurrence of a mounting error.

According to an embodiment of the present disclosure, there is provided a mounting apparatus including a first mounting head, a second mounting head, and a controller.

The first mounting head and the second mounting head are configured to each repeat a holding operation of holding an electronic component and a mounting operation of mounting the electronic component held on a substrate to alternately mount the electronic components on the substrate.

The controller is configured to compare, when the first mounting head and the second mounting head complete the holding operation and are each in a state of being capable of mounting the electronic component, a first value relating to a remaining mounting time period of the first mounting head and a second value relating to a remaining mounting time period of the second mounting head, to cause the mounting operation by the mounting head corresponding to a larger value between the first value and the second value to be preferentially performed.

The “first value” is a value relating to a time period necessary for mounting of remaining electronic components on the substrate (remaining mounting time period) out of all the electronic components to be mounted by the first mounting head. The “second value” is a value relating to a time period necessary for mounting of remaining electronic components on the substrate out of all the electronic components to be mounted by the second mounting head. As the “first value” and the “second value”, for example, a value that indicates a remaining mounting time period for the mounting heads, a value that indicates the number of remaining electronic components, or the like are used.

In the mounting apparatus, when the two mounting heads are in the state of being capable of mounting the electronic components, the mounting operation by the mounting head having a relatively larger value of the remaining mounting time period (number of remaining electronic components) is caused to be preferentially performed. With such a process, for example, even if a mounting error based on a non-sucking error or the like is generated, with the result that an additional operation for an error correction has to be performed, or an order of mounting is disturbed, which may increase a substrate production time period, it is possible to suppress the increase of the substrate production time period.

In the mounting apparatus, the controller may calculate an absolute value of a difference between the first value and the second value, determine whether the absolute value of the difference is equal to or more than a predetermined threshold value, and when the absolute value of the difference is equal to or more than the predetermined threshold value, compare the first value and the second value.

By using the threshold value, it is possible to prevent the mounting operations by the two mounting heads from being alternately changed with a slight difference between the remaining mounting time periods (number of remaining electronic components).

In the mounting apparatus, when the mounting operation by one of the first mounting head and the second mounting head is preferentially performed through the comparison between the first value and the second value, the controller may prevent a process of causing the mounting operation by the mounting head corresponding to the larger value between the first value and the second value to be preferentially performed, which is based on the comparison between the first value and the second value, from being executed until the mounting head that is caused to preferentially perform the mounting operation entirely mounts the electronic components held.

As a result, it is possible to effectively suppress the increase of the substrate production time period due to an error such as a non-sucking error.

In the mounting apparatus, each time one of the electronic components held by the first mounting head is mounted on the substrate, the controller may subtract a subtraction value relating to a time period necessary for mounting of the one electronic component from the first value, and each time one of the electronic components held by the second mounting head is mounted on the substrate, the controller may subtract a subtraction value relating to a time period necessary for mounting of the one electronic component from the second value.

In the mounting apparatus, each time the first mounting head mounts entire electronic components to be mounted in one mounting operation on the substrate, the controller may subtract a subtraction value relating to a time period necessary for mounting of the entire electronic components to be mounted in the one mounting operation from the first value, and each time the second mounting head mounts entire electronic components to be mounted in one mounting operation on the substrate, the controller may subtract a subtraction value relating to a time period necessary for mounting of the entire electronic components to be mounted in the one mounting operation from the second value.

In the mounting apparatus, the first value may be a value that indicates a remaining mounting time period of the first mounting head, and the second value may be a value that indicates a remaining mounting time period of the second mounting head.

In the mounting apparatus, the first value may be a value that indicates a remaining count of the electronic components which are mounted by the first mounting head, and the second value may be a value that indicates a remaining count of the electronic components which are mounted by the second mounting head.

According to another embodiment of the present disclosure, there is provided a method of mounting an electronic component including comparing, in a case where a first mounting head and a second mounting head that each repeat a holding operation of holding an electronic component and a mounting operation of mounting the electronic component held on a substrate to alternately mount the electronic components on the substrate complete the holding operation and are each in a state of being capable of mounting the electronic component, a first value relating to a remaining mounting time period of the first mounting head and a second value relating to a remaining mounting time period of the second mounting head.

The mounting operation by the mounting head corresponding to a larger value between the first value and the second value is caused to be preferentially performed.

According to another embodiment of the present disclosure, there is provided a method of manufacturing a substrate including comparing, in a case where a first mounting head and a second mounting head that each repeat a holding operation of holding an electronic component and a mounting operation of mounting the electronic component held on a substrate to alternately mount the electronic components on the substrate complete the holding operation and are each in a state of being capable of mounting the electronic component, a first value relating to a remaining mounting time period of the first mounting head and a second value relating to a remaining mounting time period of the second mounting head.

The mounting operation by the mounting head corresponding to a larger value between the first value and the second value is caused to be preferentially performed, thereby mounting the electronic component on the substrate.

According to another embodiment of the present disclosure, there is provided a program causing a mounting apparatus to execute a step of comparing, in a case where a first mounting head and a second mounting head that each repeat a holding operation of holding an electronic component and a mounting operation of mounting the electronic component held on a substrate to alternately mount the electronic components on the substrate complete the holding operation and are each in a state of being capable of mounting the electronic component, a first value relating to a remaining mounting time period of the first mounting head and a second value relating to a remaining mounting time period of the second mounting head, and a step of causing the mounting operation by the mounting head corresponding to a larger value between the first value and the second value to be preferentially performed.

As described above, according to the embodiments of the present disclosure, it is possible to provide a technique of the mounting apparatus and the like capable of suppressing the increase of the substrate production time period due to the occurrence of the mounting error.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a front view showing a mounting apparatus according to an embodiment of the present disclosure;

FIG. 2 is a plan view showing the mounting apparatus of FIG. 1;

FIG. 3 is a diagram for comparing a normal operation in which a mounting error of an electronic component is not generated, an operation in the case where the mounting error is generated in a mounting apparatus according to a comparative example, and an operation in the case where the mounting error is generated in the mounting apparatus according to the embodiment; and

FIG. 4 is a flowchart showing a process of a controller of the mounting apparatus.

### DETAILED DESCRIPTION OF EMBODIMENTS

Hereinafter, an embodiment of the present disclosure will be described with reference to the drawings.

(Structure Of Mounting Apparatus 100 And Structures Of Respective Components)

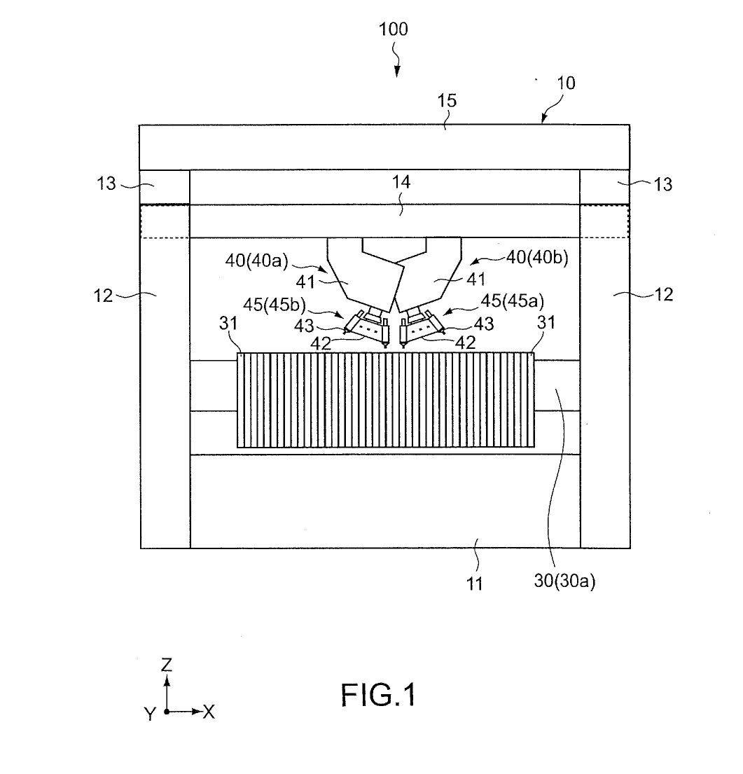

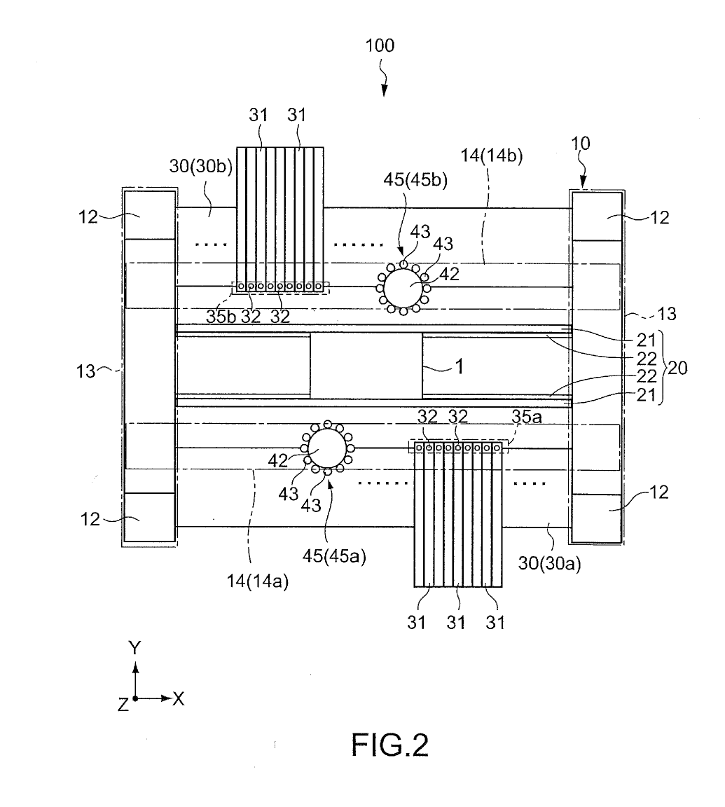

FIG. 1 is a front view showing a mounting apparatus 100 according to a first embodiment of the present disclosure. FIG. 2 is a plan view showing the mounting apparatus 100 of FIG. 1.

As shown in those figures, the mounting apparatus 100 is provided with a frame structure body 10, a conveyance unit 20 for conveying a substrate 1, which is provided to the frame structure body 10, and two tape feeder equipment unit 30 to which tape feeders 31 for supplying electronic components are equipped. Further, the mounting apparatus 100 is provided with two mounting mechanisms 40 each of which sucks an electronic component supplied from the tape feeders 31 and mounts the electronic component sucked on the substrate 1.

It should be noted that the mounting apparatus 100 has a controller (not shown) such as a CPU (Central Processing Unit) that performs overall control of the units of the mounting apparatus 100. Further, the mounting apparatus 100 has a nonvolatile memory in which various programs necessary for the control by the controller are stored and a volatile memory used as a work area of the controller. The various programs may be read by a portable recording medium such as an optical disk and a semiconductor memory.

The frame structure body 10 includes a base 11 provided on a bottom portion and a plurality of support columns 12 fixed to the base 11. Further, the frame structure body 10 includes two Y beams 13 provided across upper portions of the plurality of support columns 12 in the Y-axis direction and two X beams 14 that are extended between the two Y beams 13 along the X axis and are capable of moving in a Y-axis direction by the Y beams 13. Furthermore, the frame structure body 10 includes a top panel 15 provided on the two Y beams 13. It should be noted that in FIG. 2, the top panel 15 is not shown to help understanding of the figure, and the two X beams 14 and the two Y beams 13 on the front side are shown with alternate long and short dash lines.

The conveyance unit 20 includes a guide 21 provided along the X-axis direction and a conveyor 22 provided on the side of the center as compared to the guide 21. By driving the conveyor 22, the conveyance unit 20 conveys the substrate 1 and positions the substrate on a predetermined position or discharges the substrate 1 on which the mounting of the electronic component is terminated.

The mounting apparatus 100 has a first tape feeder equipment unit 30a on the front side (lower side in FIG. 2) and a second tape feeder equipment unit 30b on the rear side (upper side in FIG. 2). The two tape feeder equipment units 30 are disposed on such positions that the conveyance unit 20 is disposed therebetween. In the two tape feeder equipment units 30, the plurality of tape feeders 31 are arranged along the X-axis direction. The tape feeders 31 each include a reel around which a carrier tape that accommodates the electronic components therein is wound and a feed mechanism that feeds the carrier tape in step feed. Inside the carrier tape, the electronic components such as an IC chip, a resistor, a capacitor, and a coil are accommodated for each type. A supply window 32 is formed on an upper surface at an end portion of each of the tape feeders 31, and the electronic components are supplied via the supply window 32.

In the following description, an area in which the supply windows 32 of the plurality of tape feeders 31 equipped to the first tape feeder equipment unit 30a are collectively formed is referred to as a first supply area 35a. On the other hand, an area in which the supply windows 32 of the plurality of tape feeders 31 equipped to the second tape feeder equipment unit 30b are collectively formed is referred to as a second supply area 35b.

The mounting apparatus 100 has a first mounting mechanism 40a on the front side (lower side in FIG. 2) and a second mounting mechanism 40b on the rear side (upper side in FIG. 2).

The first mounting mechanism 40a includes a carriage 41 held by a first X beam 14a so as to be movable and a first mounting head 45a provided on the lower side of the carriage 41. The second mounting mechanism 40b has the same structure as the first mounting mechanism 40a except that the second mounting mechanism 40b and the first mounting mechanism 40a are formed so as to be symmetrical with respect to a Z-Y plane. That is, the second mounting mechanism 40b includes the carriage 41 held by a second X beam 14b so as to be movable and a second mounting head 45b provided on the lower side of the carriage 41.

The first mounting head 45a is movable in the X-Y directions by the Y beam 13 and the first X beam 14a and therefore can be moved between the first supply area 35a and the substrate 1. The second mounting head 45b is movable in the X-Y directions by the Y beam 13 and the second X beam 14b, and therefore can be moved between the second supply area 35b and the substrate 1.

The first mounting head 45a and the second mounting head 45b each include a turret 42 rotatably attached to the carriage 41 and a plurality of sucking nozzles 43 attached to the turret 42 at regular intervals in a circumferential direction of the turret 42. The number of sucking nozzles 43 is set to twelve for each of the mounting heads 45. It should be noted that the number of sucking nozzles 43 may be one for each of the mounting heads 45 and is not particularly limited.

The turret 42 is rotatably supported by the carriage 41 about an oblique axis as a center axis. The sucking nozzles 43 are attached to the turret 42 so that axis lines of the sucking nozzles 43 tilt with respect to the rotation axis of the turret 42. The sucking nozzles 43 are each movably supported by the turret 42 along the axis-line direction. The sucking nozzles 43 rotate about the axis lines or move in the axis-line direction by a nozzle drive mechanism (not shown) at a predetermined timing. Further, the sucking nozzles 43 are connected to an air compressor (not shown). In accordance with switching of a negative pressure and a positive pressure of the air compressor, the sucking nozzles 43 can suck or release the electronic components.

Out of the plurality of sucking nozzles 43, the sucking nozzle 43 disposed on a lowermost position has the axis line directed toward a vertical line. In the following description, the position of the sucking nozzle 43 which has the axis line directed toward the vertical line is referred to as an operation position. The sucking nozzle 43 disposed on the operation position is sequentially switched by rotating the turret 42. Typically, out of the plurality of sucking nozzles 43, the sucking nozzle 43 disposed on the operation position is moved in the vertical direction by the nozzle drive mechanism, or the negative pressure and the positive pressure thereof is switched by the air compressor.

The first mounting head 45a moves to the first supply area 35a, sucks target electronic components by the plurality of sucking nozzles 43, moves to the position above the substrate 1, and mounts the electronic components sucked by the sucking nozzles 43 on the substrate 1.

The mounting apparatus 100 is provided with a camera (not shown). The camera is provided to each of the first mounting mechanism 40a and the second mounting mechanism 40b. The camera has an image pickup element such as a CCD (Charge Coupled Device) or a CMOS (Complementary Metal Oxide Semiconductor), and the image pickup unit takes an image of the electronic component sucked by the sucking nozzle 43. The camera is provided so as to move integrally with the mounting mechanism 40, for example, and takes an image of a sucked state of the electronic component through an optical system such as a mirror (not shown).

The camera takes an image of the electronic component sucked by the sucking nozzle 43 when the sucking nozzle 43 that sucks the electronic component is moved to a predetermined position by the rotation of the turret 42. For example, at a time when the sucking nozzle 43 that sucks the electronic component is moved to the highest position by the rotation of the turret 42, the camera takes an image of the electronic component. The image taken by the camera is subjected to image processing by the controller, and whether the electronic component is sucked by the sucking nozzle 43 or not and the sucked position of the electronic component with respect to the sucking nozzle 43 are determined, for example.

(Explanation Of Operation)

Next, an operation of the mounting apparatus 100 according to this embodiment will be described. It should be noted that each processing of the mounting apparatus 100 described below is performed under the control by the controller.

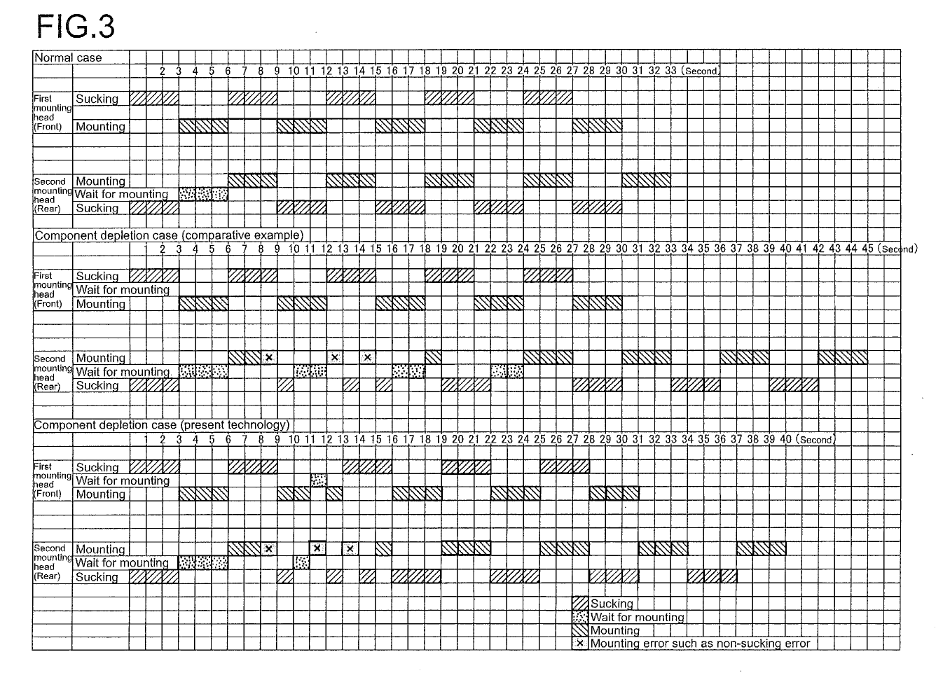

FIG. 3 is a diagram showing a comparison among a normal operation in which a mounting error of the electronic component is not generated, an operation in the case where the mounting error is generated in the mounting apparatus according to a comparative example, and an operation in the case where the mounting error is generated in the mounting apparatus 100 according to this embodiment.

“Normal operation (operation in case where mounting error is not generated)”

First, with reference to an upper diagram of FIG. 3, a description will be given on the normal operation in which the mounting error of the electronic component is not generated in the mounting apparatus 100 according to this embodiment or in the mounting apparatus 100 according to the comparative example.

In the description on the operation of the mounting apparatus 100, to facilitate understanding, the first mounting head 45a and the second mounting head 45b each have three sucking nozzles 43, one sucking operation causes three electronic components to be sucked, and one mounting operation causes the three electronic components to be mounted on the substrate. In addition, to facilitate understanding, a time period necessary to suck one electronic component is set to 1 second (3 seconds for one sucking operation), and a time period necessary to mount one electronic component is set to 1 second (3 seconds for one mounting operation).

First, the substrate 1 is conveyed by the conveyance unit 20, and the substrate 1 is positioned to a predetermined position. Then, the first mounting head 45a (front side) is moved to a position above the first supply area 35a, and at the same time, the second first mounting head 45b (rear side) is moved to a position above the second supply area 35b.

Subsequently, the sucking nozzle 43 disposed on the operation position is moved downward, and the sucking nozzle 43 is switched to the negative pressure by the air compressor. As a result, the electronic component is sucked by a tip end portion of the sucking nozzle 43. When the electronic component is sucked, the sucking nozzle 43 that has sucked the electronic component is moved upward.

Next, the turret 42 is rotated, and the sucking nozzle 43 disposed on the operation position is switched. When the sucking nozzle 43 disposed on the operation position is switched, the sucking nozzle 43 is moved downward, and an electronic component is sucked by the tip end of the sucking nozzle 43. In this way, the electronic components are sucked by the three sucking nozzles 43 of each of the first mounting head 45a and the second mounting head 45b.

After the elapse of 3 seconds, upon sucking of the electronic components by the three sucking nozzles 43 of each of the first mounting head 45a and the second mounting head 45b, the first mounting head 45a is moved from the first supply area 35a to a position above the substrate 1. On the other hand, the second mounting head 45b is moved from the second supply area 35b to a standby position.

The standby position of the second mounting head 45b is such a position that the second mounting head 45b does not interfere with the first mounting head 45a. For example, the standby position of the second mounting head 45b is such a position that even when the first mounting head 45a during execution of the mounting operation approaches the second mounting head 45b side, the second mounting head 45b is not in contact with the first mounting head 45a. The standby position is not limited to a fixed position and may be changeable depending on the movement of the first mounting head 45a during execution of the mounting operation. Herein, the standby position of the second mounting head 45b is described, and the same holds true for the standby position of the first mounting head 45a.

When the first mounting head 45a is moved to a position above the substrate, the position of the sucking nozzle 43 disposed on the operation position and the position of the substrate 1 on which the electronic component is mounted are aligned with each other. Upon alignment of the position of the sucking nozzle 43 with the position of the substrate 1, the sucking nozzle 43 in the state of holding the electronic component is moved downward, and the sucking nozzle 43 is switched from the negative pressure to the positive pressure by the air compressor. As a result, the electronic component is released from the sucking nozzle 43, and the electronic component is mounted on the substrate 1. Upon mounting of the electronic component on the substrate 1, the sucking nozzle 43 is moved upward and distanced from the substrate 1.

Next, the turret 42 is rotated, and the sucking nozzle 43 disposed on the operation position is switched. When the sucking nozzle 43 disposed on the operation position is switched, the sucking nozzle 43 is moved downward, and the electronic component sucked by the tip end of the sucking nozzle 43 is mounted on the substrate 1. In this way, the three electronic components held by the three sucking nozzles 43 are mounted on the substrate.

After the elapse of 6 seconds, upon termination of the one mounting operation by the first mounting head 45a, the first mounting head 45a is moved to the first supply area 35a and starts the sucking operation. On the other hand, after the elapse of 6 seconds, the second mounting head 45b is moved to the position above the substrate and starts the mounting operation.

Basically, the first mounting head 45a sucks the electronic components in the first supply area 35a during the mounting of the electronic components on the substrate 1 by the second mounting head 45b. The second mounting head 45b mounts the electronic components on the substrate 1 during the sucking of the electronic components in the first supply area 35a by the first mounting head 45a. As described above, the first mounting head 45a and the second mounting head 45b repeat the sucking operation for sucking the electronic components (holding operation for holding the electronic components) and the mounting operation for mounting the sucked electronic components on the substrate, thereby mounting the electronic components on one substrate alternately.

As shown in the upper diagram of FIG. 3, in the case of the normal operation in which the mounting error is not generated, it takes 33 seconds to complete the mounting of the electronic components on the substrate.

“Operation at time when mounting error is generated in mounting apparatus 100 according to comparative example”

Next, a description will be given on the case where the mounting error is generated in the mounting apparatus 100 according to the comparative example with reference to the center diagram of FIG. 3.

In the center diagram of FIG. 3, after the elapse of 8 seconds, for example, the mounting error of an electronic component is generated in the second mounting head 45b (rear side). Examples of the mounting error include a mounting error due to the non-sucking error of the electronic component and a mounting error due to the sucking of a defective component. It should be noted that in FIG. 3, an example of the case where the mounting error is generated due to the non-sucking error of the electronic component will be described for convenience.

After the elapse of 9 seconds, in order to suck an electronic component that has caused the mounting error, the second mounting head 45b is moved to the second supply area 35b and sucks the electronic component. On the other hand, after the elapse of 9 seconds, the first mounting head 45a (front side) starts a mounting operation for mounting three electronic components sucked by the three sucking nozzle 43 thereof on the substrate.

After the elapse of 10 seconds, the second mounting head 45b holds the electronic component (one) that has caused the mounting error by the sucking nozzle 43 (actually, not hold) and is brought into the state in which the second mounting head can mount the electronic component. However, at the time when 10 seconds elapse, the first mounting head 45a is performing the mounting operation, so the second mounting head 45b is moved to the standby position to wait until the first mounting head 45a terminates the mounting operation.

After the elapse of 12 seconds, the first mounting head 45a terminates the mounting of the three electronic components on the substrate and is then moved to the first supply area 35a. After the elapse of 12 seconds, because the first mounting head 45a is moved to the supply area 35, the second mounting head 45b is moved to the position above the substrate from the standby position. Then, the second mounting head 45b tries to mount the electronic component that has caused the mounting error on the substrate again. However, the mounting error due to the non-sucking error is generated again, and the mounting of the electronic component on the substrate is failed.

After the elapse of 13 seconds, in order to suck the electronic component (one) that has caused the mounting error, the second mounting head 45b is moved to the second supply area 35b. After the elapse of 14 seconds, the second mounting head 45b holds the electronic component that has caused the mounting error and tries to mount the electronic component on the substrate again. However, the mounting error is generated again.

Here, in the case where non-sucking errors are generated three times in succession in the same tape feeder 31, the controller determines that there is no electronic component in the tape feeder 31, that is, a component depletion of the electronic components is generated. Then, the controller supplies electronic components depleted from another tape feeder 31 and controls the mounting heads 45 to suck the electronic components on the position of the tape feeder 31 (so-called alternate process). It should be noted that such a process is also performed in the mounting apparatus 100 according to this embodiment.

After the elapse of 15 seconds, through the alternate process, the second mounting head 45b is moved to the position of the supply window of the tape feeder 31 serving as a new supply source of the electronic components, and an electronic component is sucked by the sucking nozzle 43. After the elapse of 16 seconds, the second mounting head 45b is brought into the state where the second mounting head can mount the electronic component on the substrate but stands by at the standby position, because the first mounting head 45a is performing the mounting operation. After the elapse of 18 seconds, the first mounting head 45a is moved to the first supply area 35a, and the second mounting head 45b is moved to the position above the substrate, to mount the electronic component that has caused the mounting error. Because the alternate process has been carried out, the mounting of the electronic component after the elapse of 18 seconds is succeeded.

After the elapse of 19 seconds, the second mounting head 45b is moved to the second supply area 35b and starts the sucking operation for sucking three electronic components with the three sucking nozzles 43. After the elapse of 22 seconds, the second mounting head 45b terminates the sucking operation and is brought into the state where the second mounting head can mount the electronic component on the substrate. However, at the time when 22 seconds elapse, the first mounting head 45a is performing the mounting operation, so the second mounting head 45b is moved to the standby position and waits until the mounting operation by the first mounting head 45a is terminated.

After the elapse of 24 seconds, the first mounting head 45a is moved to the first supply area 35a and starts the sucking operation. On the other hand, after the elapse of 24 seconds, the second mounting head 45b is moved to the position above the substrate and starts the mounting operation. In the following, the same operation as the normal operation is carried out, and due to the occurrence of the mounting error, the second mounting head 45b performs the mounting operations three times after the completion of the mounting of the electronic components by the first mounting head 45a. In this example, it takes 45 seconds to complete the mounting of the electronic components on the substrate. During the three mounting operations by the second mounting head 45b, the first mounting head 45a performs nothing, which causes wasted time. In actuality, a time period for the additional operation of the second mounting head 45b due to the non-sucking error is 6 seconds. However, the additional time period necessary for the entire mounting apparatus 100 is 12 seconds, which shows that the wasted time period of 6 seconds is generated.

In view of the above, in this embodiment, it is desirable to provide a technique of saving such a wasted time period.

“Operation at time when mounting error is generated in mounting apparatus 100 according to this embodiment”

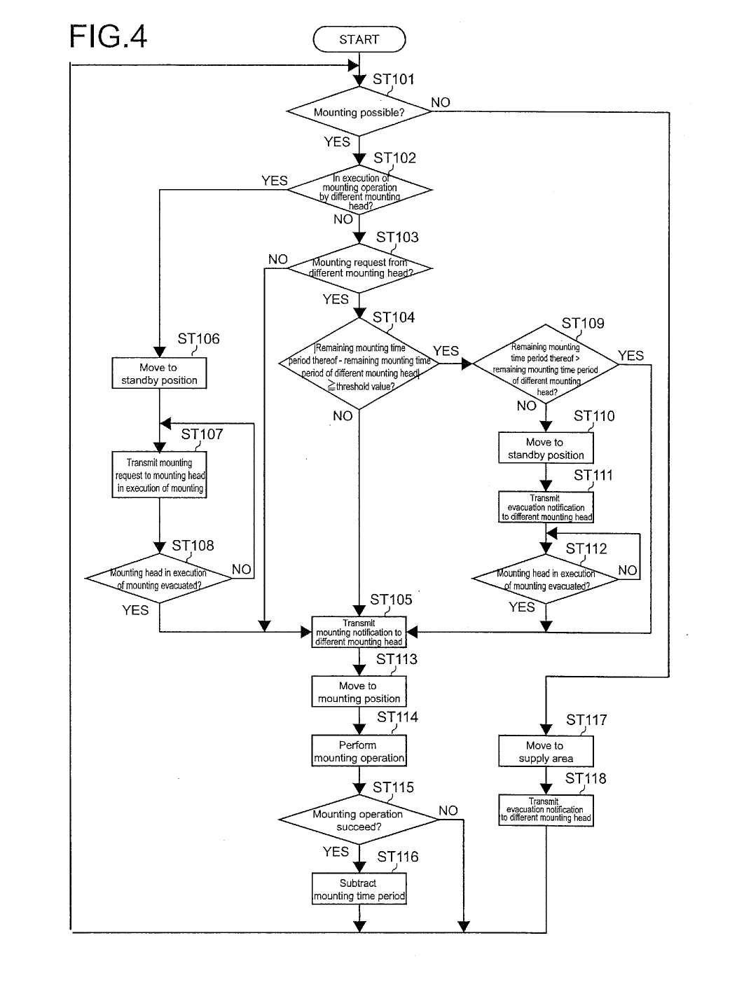

Next, a description will be given on an operation at the time when the mounting error is generated in the mounting apparatus 100 according to this embodiment. In the lower diagram of FIG. 3, an example of an operation at the time when the mounting error is generated is shown. FIG. 4 is a flowchart showing a process of the controller of the mounting apparatus 100 according to this embodiment. The first mounting head 45a and the second mounting head 45b each perform the process of the flowchart independently of each other.

First, the process shown in FIG. 4 will be described.

As shown in FIG. 4, first, the controller determines whether the mounting head 45 controlled by the controller concerned terminates the sucking operation of the electronic components and is in the state of being capable of mounting the electronic components on the substrate or not (Step 101). In the case where the mounting head 45 is not in the state of being capable of mounting the electronic components (NO in Step 101), the controller moves the mounting head 45 to the supply area 35 (Step 117). Then, the controller transmits an evacuation notification to the controller of a different mounting head 45 (Step 118).

On the other hand, in the case where the mounting head 45 completes the sucking operation of the electronic components and is in the state of being capable of mounting the electronic components on the substrate (YES in Step 101), the controller determines whether the different mounting head 45 is performing the mounting operation on the substrate or not at this time (Step 102).

In the case where the different mounting head 45 is performing the mounting operation (YES in Step 102), the controller moves the mounting head 45 to the standby position (Step 106). Then, the controller transmits a mounting request notification to the controller of the different mounting head 45 which is performing the mounting operation (Step 107) and determines whether the different mounting head 45 evacuates or not (Step 108).

In the case where the different mounting head 45 which is performing the mounting operation does not evacuate (NO in Step 108), the controller transmits again the mounting request notification to the controller of the different mounting head 45 and determines again whether the different mounting head 45 evacuates or not. In other words, in the case where the different mounting head 45 is performing the mounting operation, the controller causes the mounting head 45 to stand by at the standby position until the different mounting head 45 evacuates.

In Step 102, in the case where the different mounting head 45 is not performing the mounting operation (NO in Step 102), the controller determines whether the mounting request notification is received from the different mounting head 45 or not (Step 103). In the case where the mounting request notification is not received from the different mounting head 45 (NO in Step 103), the controller transmits, to the controller of the different mounting head 45, a mounting notification indicating that the mounting head 45 controlled by the controller concerned performs the mounting (Step 105). Then, the controller causes the mounting head 45 to move to the mounting position above the substrate (Step 113), and the mounting head performs the mounting operation of an electronic component (Step 114).

In Step 103, in the case where the mounting request notification is received from the different mounting head 45 (YES in Step 103), the controller performs the next Step 104. In Step 104, the controller calculates an absolute value of a difference between a remaining mounting time period of the mounting head 45 controlled by the controller concerned (first value or second value) and a mounting time period of the different mounting head 45 (second value or first value) and determines whether the absolute value of the difference is equal to or more than a predetermined threshold value or not.

The remaining mounting time period means a time period necessary for mounting electronic components that are not mounted yet out of all the electronic components to be mounted by the mounting head 45. For example, in the example of FIG. 3, after the elapse of 3 seconds, the remaining mounting time period of the first mounting head 45a and the second mounting head 45b is 15 seconds (see “mounting” boxes). As will be described later, each time one electronic component is mounted, a time period necessary for the mounting of one electronic component (1 second) (subtraction value) is subtracted from 15 seconds (initial value).

For example, generally, the predetermined threshold value is set to a time period equal to or more than a time period (3 seconds in the example of FIG. 3) necessary for the mounting of all the electronic components (three in the example of FIG. 3) to be mounted in one mounting operation by the mounting head 45.

In the case where the absolute value of the difference is equal to or more than the threshold value (YES in Step 104), the controller determines whether the remaining mounting time period of the mounting head 45 controlled by the controller concerned exceeds the remaining mounting time period of the different mounting head 45 or not (Step 109).

In the case where the remaining mounting time period of the mounting head 45 controlled by the controller concerned exceeds the remaining mounting time period of the different mounting head 45 (YES in Step 109), the controller transmits the mounting notification to the controller of the different mounting head 45 (Step 105). Then, the controller causes the mounting head 45 to move to the mounting position above the substrate (Step 113) and perform the mounting operation of one electronic component (Step 114).

That is, in the case where the remaining mounting time period of the mounting head 45 controlled by the controller concerned exceeds the remaining mounting time period of the different mounting head 45 (YES in Step 109), the mounting operation by the mounting head 45 controlled by the controller concerned is preferentially performed.

On the other hand, in the case where the remaining mounting time period of the mounting head 45 controlled by the controller concerned is equal to or less than the remaining mounting time period of the different mounting head 45 (NO in Step 109), the controller causes the mounting head 45 to move to the standby position (Step 110) and transmits an evacuation notification to the controller of the different mounting head 45 (Step 111).

In other words, in the case where the remaining mounting time period of the mounting head 45 controlled by the controller concerned is equal to or less than the remaining mounting time period of the different mounting head 45, even if the mounting operation is being performed, the controller yields precedence to the different mounting head 45 to perform the mounting operation in order to cause the mounting operation by the different mounting head 45 to be preferentially performed.

Upon transmission of the evacuation notification to the controller of the different mounting head 45, the controller then determines whether the different mounting head 45 which is performing the mounting operation evacuates or not (Step 112).

In the case where the absolute value of the different is less than the threshold value in Step 104 (NO in Step 104), the controller transmits the mounting notification to the controller of the different mounting head 45 (Step 105). Then, the controller causes the mounting head 45 to move to the mounting position above the substrate (Step 113) and to perform the mounting operation of the electronic component (one) (Step 114).

That is, in the case where the absolute value of the difference between the remaining mounting time periods of the two mounting heads 45 is less than the threshold value, the process of causing one of the two mounting heads 45 to preferentially perform the mounting operation which is based on a comparison between the remaining mounting time periods of the two mounting heads 45 is not performed, and the same operation as the normal operation is performed.

With reference to Step 108, for example, in the case where the evacuation notification in Step 111 is received, that is, the mounting operation is preferentially performed on the basis of the comparison between the mounting time periods (YES in Step 108), the process proceeds to the next Step 105. It should be noted that when the different mounting head 45 is moved to the supply area 35, the evacuation notification is transmitted from the different mounting head 45 (see Step 118), and the evacuation notification is received, with the result that the controller may perform the next Step 105.

In Step 105, the controller transmits the mounting notification to the controller of the different mounting head 45. Then, the controller causes the mounting head 45 to move to the mounting position above the substrate (Step 113) and perform the mounting operation of the electronic component (one) (Step 114).

With reference to Step 112, in the case where the different mounting head 45 is moved to the supply area 35, the evacuation notification is transmitted from the different mounting head 45 (see Step 118), and the evacuation notification is received (YES in Step 112), the controller transmits the mounting notification to the different mounting head 45 (Step 105). Then, the controller causes the mounting head 45 to move to the mounting position above the substrate (Step 113) and perform the mounting operation of the electronic component (one) (Step 114).

In the case where the mounting operation is performed, the controller determines whether the mounting operation of the electronic component on the substrate is succeeded or not (Step 115). In the case where the controller determines that the mounting operation is succeeded (YES in Step 115), a process of subtracting the mounting time period is performed (Step 116), and the process returns to Step 101. In Step 116, the controller subtracts a time period (1 second in the example of FIG. 3) (subtraction value) necessary for the mounting of one electronic component from a current remaining mounting time period of the mounting head 45.

In Step 115, in the case where the controller determines that the mounting operation is failed (NO in Step 115), the controller performs Step 101 again without performing the process of subtracting the mounting time period.

Through the process described above, the mounting operation of the mounting head 45 which has a longer remaining mounting time period relative to that of the different mounting head 45 is preferentially performed. As a result, for example, even in the case where the mounting error is generated due to the non-sucking error or the like, and therefore the additional operation has to be performed to correct the error, or the order of mounting is disturbed, and therefore a substrate production time period becomes longer, it is possible to suppress the substrate production time period from being increased.

Further, in this embodiment, in the case where the absolute value of the difference between the remaining mounting time periods of the two mounting heads 45 is equal to or more than the predetermined threshold value, a process of comparing the remaining mounting time periods is performed to determine whether the mounting by one mounting head 45 is preferentially performed or not. On the other hand, in the case where the absolute value of the difference is less than the predetermined threshold value, the process of comparing the remaining mounting time periods of the two mounting heads 45 is not performed, and the same operation as the normal operation is performed. As a result, it is possible to prevent the two mounting heads 45 from yielding precedence to each other alternately by a short difference between the remaining mounting time periods.

Next, with reference to the lower diagram of FIG. 3, an operation in the case where the mounting error is generated is described in detail. It should be noted that the assumption is made that the predetermined threshold value (see Step 104) is 3 seconds here.

First, the first mounting head 45a (front side) is moved to the first supply area 35a, and at the same time, the second mounting head 45b (rear side) is moved to the second supply area 35b.

After the elapse of 3 seconds, when the electronic components are sucked by the three sucking nozzles 43 of the first mounting head 45a and the second mounting head 45b, respectively, the first mounting head 45a is moved from the first supply area 35a to the position above the substrate 1. On the other hand, the second mounting head 45b is moved from the second supply area 35b to the standby position.

Attention is directed toward time after the elapse of 4 seconds. When 4 seconds elapse, the first mounting head 45a succeeds in the mounting operation of one electronic component. Therefore, at this time, the remaining mounting time period of the first mounting head 45a is 15−1 (initial value−time period necessary for the mounting of one electronic component)=14 seconds (Step 116). When 4 seconds elapse, the second mounting head 45b stands by at the standby position (Step 108), and the remaining mounting time period thereof is 15 seconds. When 4 seconds elapse, the absolute value of the difference between the two mounting heads 45 is less than the threshold value (3 seconds) (NO in Step 104). Thus, in the 4-second range, the first mounting head 45a basically performs the same operation as the normal operation (Steps 113 and 114).

After the elapse of 5 seconds, the first mounting head 45a succeeds in the mounting operation of two electronic components. Therefore, at this time, the remaining mounting time period of the first mounting head 45a is 15−2=13 seconds (Step 116). On the other hand, the remaining mounting time period of the second mounting head 45b is 15 seconds. When 5 seconds elapse, the difference of the two mounting heads 45 is less than the threshold value (3 seconds) (NO in Step 104). Thus, in the 5-second range, the first mounting head 45a basically performs the same operation as the normal operation.

When 6 seconds elapse, the first mounting head 45a succeeds in the mounting operation of the three electronic components. Therefore, at this time, the remaining mounting time period of the first mounting head 45a is 12 seconds (Step 116). On the other hand, the remaining mounting time period of the second mounting head 45b is still 15 seconds.

In the 6-second range, the first mounting head 45a is moved to the first supply area 35a in order to suck the electronic component (Step 117) and transmits the evacuation notification to the second mounting head 45b (Step 118). On the other hand, upon reception of the evacuation notification transmitted from the first mounting head 45a (YES in Step 108), the second mounting head 45b transmits the mounting notification to the first mounting head 45a (Step 105), and then is moved to the mounting position (Step 113) to perform the mounting operation (Step 114).

When 8 seconds elapse, the second mounting head 45b succeeds in the mounting operation of the two electronic components. Therefore, at this time, the remaining mounting time period of the second mounting head 45b is 15−2=13 seconds (Step 116).

In the 8-second range, the second mounting head 45b fails in the mounting operation of the electronic component (NO in Step 115). Therefore, after the elapse of 9 seconds, the remaining mounting time period of the second mounting head 45b is 13 seconds.

In the 9-second range, the second mounting head 45b is moved to the second supply area 35b to suck the electronic component which has not been mounted unsuccessfully (Step 117). On the other hand, the first mounting head 45a starts the mounting operation of the electronic component.

After the elapse of 10 seconds, the remaining mounting time period of the first mounting head 45a is 11 seconds. On the other hand, the remaining mounting time period of the second mounting head 45b is 13 seconds. At the time when 10 seconds elapse, both the two mounting heads 45 are in the state where the mounting heads 45 can mount the electronic components. In the 10-second range, the absolute value of the difference between the mounting time periods of the two mounting heads 45 is less than the predetermined threshold value (3 seconds) (YES in Step 101), so the first mounting head 45a performs the mounting operation. On the other hand, the second mounting head 45b is moved to the standby position (Step 106) to wait until the first mounting head 45a evacuates (Step 108).

After the elapse of 11 seconds, the remaining mounting time period of the first mounting head 45a is 10 seconds, and the remaining mounting time period of the second mounting head 45b is 13 seconds. In the 11-second range, the absolute value of the difference between the remaining mounting time periods of the two mounting heads 45 is equal to or more than 3 seconds (YES in Step 103), and the remaining mounting time period of the first mounting head 45a is small (NO in Step 109), so the first mounting head 45a is moved to the standby position (Step 110). Then, the first mounting head 45a transmits the evacuation notification to the second mounting head 45b (Step 111). On the other hand, upon reception of the evacuation notification transmitted from the first mounting head 45a (YES in Step 108), the second mounting head 45b performs the mounting operation of the electronic component. However, the second mounting head 45b fails in the mounting operation (NO in Step 115), so the remaining mounting time period of the second mounting head 45b is 13 seconds.

In the 12-second range, the second mounting head 45b is moved to the second supply area 35b to suck the electronic component that has not been mounted unsuccessfully (Step 117) and transmits the evacuation notification to the first mounting head 45a (Step 118). On the other hand, upon reception of the evacuation notification transmitted from the second mounting head 45b (YES in Step 112), the first mounting head 45a performs the mounting operation of the electronic component.

In the 13-second range, the first mounting head 45a is moved to the first supply area 35a to suck the electronic component (Step 117) and starts the sucking operation. On the other hand, the second mounting head 45b performs the mounting operation of the electronic component that has not been mounted unsuccessfully. However, the second mounting head 45b fails again in the mounting operation of the electronic component this time (NO in Step 115).

In the 14-second range, the second mounting head 45b is moved to the position of the supply window of the tape feeder 31 newly serving as the supply source of the electronic components through the alternate process, to suck one electronic component. In the 15-second range, the second mounting head 45b succeeds in the mounting operation of the electronic components.

After that, the first mounting head 45a and the second mounting head 45b repeat the sucking operation of the three electronic components and the mounting operation of the three electronic components alternately as in the case of the normal operation while subtracting the remaining mounting time periods.

In this example, the time periods of the additional operation by the second mounting head 45b due to the non-sucking error is 6 seconds, and the additional time period as the entire mounting apparatus 100 is 7 seconds. In this way, according to this embodiment, it is possible to suppress the wasted time. When the center diagram of FIG. 3 and the lower diagram of FIG. 3 are compared with each other, in this embodiment, the wasted time period of 5 seconds can be shortened as compared to the comparative example. It should be noted that, to facilitate the understanding, the time period necessary to suck one electronic component is set to 1 second, and the time period necessary to mount one electronic component is set to 1 second. In actuality, however, those time periods are approximately 0.3 to 0.5 second. Thus, in this embodiment, it is possible to shorten approximately 1.5 to 2.5 seconds as compared to the comparative example.

In the above description, the case where the remaining mounting time periods of the two mounting heads are compared to each other is explained, but the numbers of remaining electronic components of the two mounting heads 45 may be compared to each other. Alternatively, in addition to the remaining mounting time periods or the numbers of remaining electronic components, remaining sucking time periods, remaining movement time periods of the mounting heads 45, or the like may be considered.

Further, in the above description, each time one electronic component is mounted on the substrate out of the electronic components held by the mounting heads 45, the time period necessary to mount one electronic component is subtracted. However, the present disclosure is not limited to this case. Each time the mounting heads 45 mount all the electronic components to be mounted by one mounting operation (three in FIG. 3) on the substrate, the time period necessary to mount all the electronic components to be mounted by one mounting operation (3 seconds) may be subtracted from the remaining mounting time period. Alternatively, each time the mounting heads 45 mounts all the electronic components (three in FIG. 3) on the substrate, the number of all electronic components to be mounted by one mounting operation (three) may be subtracted from the number of remaining electronic components.

Further, by comparing the remaining mounting time periods (number of remaining electronic components) of the two mounting heads with each other, in the case where the mounting operation of one of the mounting heads 45 is preferentially performed, until all the electronic components held by the mounting head 45 which preferentially performs the mounting operation are mounted, it is possible to prevent a process of allowing one of the mounting heads to preferentially perform the mounting operation on the basis of the comparison between the remaining mounting time periods (number of remaining electronic components) from being executed. As a result, it is possible to more effectively suppress the substrate production time period from being increased.

In the above description, the two mounting heads 45 are provided. However, the present disclosure can be applied to the case where three or more mounting heads 45 are provided. In the above description, the mounting heads 45 suck the electronic components, but the present disclosure may have a form in which the mounting heads 45 each nip and hold the electronic component from both sides.

It should be noted that the present disclosure can take the following configurations.

(1) A mounting apparatus, including:

a first mounting head and a second mounting head configured to each repeat a holding operation of holding an electronic component and a mounting operation of mounting the electronic component held on a substrate to alternately mount the electronic components on the substrate; and

a controller configured to compare, when the first mounting head and the second mounting head complete the holding operation and are each in a state of being capable of mounting the electronic component, a first value relating to a remaining mounting time period of the first mounting head and a second value relating to a remaining mounting time period of the second mounting head, to cause the mounting operation by the mounting head corresponding to a larger value between the first value and the second value to be preferentially performed.

(2) The mounting apparatus according to Item (1), in which

the controller calculates an absolute value of a difference between the first value and the second value, determines whether the absolute value of the difference is equal to or more than a predetermined threshold value, and when the absolute value of the difference is equal to or more than the predetermined threshold value, compares the first value and the second value.

(3) The mounting apparatus according to Item (1) or (2), in which

when the mounting operation by one of the first mounting head and the second mounting head is preferentially performed through the comparison between the first value and the second value, the controller prevents a process of causing the mounting operation by the mounting head corresponding to the larger value between the first value and the second value to be preferentially performed, which is based on the comparison between the first value and the second value, from being executed until the mounting head that is caused to preferentially perform the mounting operation entirely mounts the electronic components held.

(4) The mounting apparatus according to any one of Items (1) to (3), in which

each time one of the electronic components held by the first mounting head is mounted on the substrate, the controller subtracts a subtraction value relating to a time period necessary for mounting of the one electronic component from the first value, and each time one of the electronic components held by the second mounting head is mounted on the substrate, the controller subtracts a subtraction value relating to a time period necessary for mounting of the one electronic component from the second value.

(5) The mounting apparatus according to any one of Items (1) to (3), in which

each time the first mounting head mounts entire electronic components to be mounted in one mounting operation on the substrate, the controller subtracts a subtraction value relating to a time period necessary for mounting of the entire electronic components to be mounted in the one mounting operation from the first value, and each time the second mounting head mounts entire electronic components to be mounted in one mounting operation on the substrate, the controller subtracts a subtraction value relating to a time period necessary for mounting of the entire electronic components to be mounted in the one mounting operation from the second value.

(6) The mounting apparatus according to any one of Items (1) to (5), in which

the first value is a value that indicates a remaining mounting time period of the first mounting head, and

the second value is a value that indicates a remaining mounting time period of the second mounting head.

(7) The mounting apparatus according to any one of Items (1) to (5), in which

the first value is a value that indicates a remaining count of the electronic components which are mounted by the first mounting head, and

the second value is a value that indicates a remaining count of the electronic components which are mounted by the second mounting head.

(8) A method of mounting an electronic component, including:

comparing, in a case where a first mounting head and a second mounting head that each repeat a holding operation of holding an electronic component and a mounting operation of mounting the electronic component held on a substrate to alternately mount the electronic components on the substrate complete the holding operation and are each in a state of being capable of mounting the electronic component, a first value relating to a remaining mounting time period of the first mounting head and a second value relating to a remaining mounting time period of the second mounting head; and causing the mounting operation by the mounting head corresponding to a larger value between the first value and the second value to be preferentially performed.

(9) A method of manufacturing a substrate, including:

comparing, in a case where a first mounting head and a second mounting head that each repeat a holding operation of holding an electronic component and a mounting operation of mounting the electronic component held on a substrate to alternately mount the electronic components on the substrate complete the holding operation and are each in a state of being capable of mounting the electronic component, a first value relating to a remaining mounting time period of the first mounting head and a second value relating to a remaining mounting time period of the second mounting head; and

causing the mounting operation by the mounting head corresponding to a larger value between the first value and the second value to be preferentially performed, thereby mounting the electronic component on the substrate.

(10) A program causing a mounting apparatus to execute

a step of comparing, in a case where a first mounting head and a second mounting head that each repeat a holding operation of holding an electronic component and a mounting operation of mounting the electronic component held on a substrate to alternately mount the electronic components on the substrate complete the holding operation and are each in a state of being capable of mounting the electronic component, a first value relating to a remaining mounting time period of the first mounting head and a second value relating to a remaining mounting time period of the second mounting head, and

a step of causing the mounting operation by the mounting head corresponding to a larger value between the first value and the second value to be preferentially performed.

The present disclosure contains subject matter related to that disclosed in Japanese Priority Patent Application JP 2011-253625 filed in the Japan Patent Office on Nov. 21, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A mounting apparatus, comprising:
a first mounting head and a second mounting head configured to each repeat a holding operation of holding an electronic component and a mounting operation of mounting the electronic component held on a substrate to alternately mount the electronic components on the substrate; and
a controller configured to compare, when the first mounting head and the second mounting head complete the holding operation and are each in a state of being capable of mounting the electronic component, a first value relating to a remaining mounting time period of the first mounting head and a second value relating to a remaining mounting time period of the second mounting head, to cause the mounting operation by the mounting head corresponding to a larger value between the first value and the second value to be preferentially performed.

2. The mounting apparatus according to claim 1, wherein
the controller calculates an absolute value of a difference between the first value and the second value, determines whether the absolute value of the difference is equal to or more than a predetermined threshold value, and when the absolute value of the difference is equal to or more than the predetermined threshold value, compares the first value and the second value.

3. The mounting apparatus according to claim 1, wherein
when the mounting operation by one of the first mounting head and the second mounting head is preferentially performed through the comparison between the first value and the second value, the controller prevents a process of causing the mounting operation by the mounting head corresponding to the larger value between the first value and the second value to be preferentially performed, which is based on the comparison between the first value and the second value, from being executed until the mounting head that is caused to preferentially perform the mounting operation entirely mounts the electronic components held.

4. The mounting apparatus according to claim 1, wherein
each time one of the electronic components held by the first mounting head is mounted on the substrate, the controller subtracts a subtraction value relating to a time period necessary for mounting of the one electronic component from the first value, and each time one of the electronic components held by the second mounting head is mounted on the substrate, the controller subtracts a subtraction value relating to a time period necessary for mounting of the one electronic component from the second value.

5. The mounting apparatus according to claim 1, wherein
each time the first mounting head mounts entire electronic components to be mounted in one mounting operation on the substrate, the controller subtracts a subtraction value relating to a time period necessary for mounting of the entire electronic components to be mounted in the one mounting operation from the first value, and each time the second mounting head mounts entire electronic components to be mounted in one mounting operation on the substrate, the controller subtracts a subtraction value relating to a time period necessary for mounting of the entire electronic components to be mounted in the one mounting operation from the second value.

6. The mounting apparatus according to claim 1, wherein
the first value is a value that indicates a remaining mounting time period of the first mounting head, and
the second value is a value that indicates a remaining mounting time period of the second mounting head.

7. The mounting apparatus according to claim 1, wherein
the first value is a value that indicates a remaining count of the electronic components which are mounted by the first mounting head, and
the second value is a value that indicates a remaining count of the electronic components which are mounted by the second mounting head.

8. A method of mounting an electronic component, comprising:
comparing, in a case where a first mounting head and a second mounting head that each repeat a holding operation of holding an electronic component and a mounting operation of mounting the electronic component held on a substrate to alternately mount the electronic components on the substrate complete the holding operation and are each in a state of being capable of mounting the electronic component, a first value relating to a remaining mounting time period of the first mounting head and a second value relating to a remaining mounting time period of the second mounting head; and
causing the mounting operation by the mounting head corresponding to a larger value between the first value and the second value to be preferentially performed.

9. A method of manufacturing a substrate, comprising:
comparing, in a case where a first mounting head and a second mounting head that each repeat a holding operation of holding an electronic component and a mounting operation of mounting the electronic component held on a substrate to alternately mount the electronic components on the substrate complete the holding operation and are each in a state of being capable of mounting the electronic component, a first value relating to a remaining mounting time period of the first mounting head and a second value relating to a remaining mounting time period of the second mounting head; and
causing the mounting operation by the mounting head corresponding to a larger value between the first value and the second value to be preferentially performed, thereby mounting the electronic component on the substrate.

10. A program causing a mounting apparatus to execute
a step of comparing, in a case where a first mounting head and a second mounting head that each repeat a holding operation of holding an electronic component and a mounting operation of mounting the electronic component held on a substrate to alternately mount the electronic components on the substrate complete the holding operation and are each in a state of being capable of mounting the electronic component, a first value relating to a remaining mounting time period of the first mounting head and a second value relating to a remaining mounting time period of the second mounting head, and
a step of causing the mounting operation by the mounting head corresponding to a larger value between the first value and the second value to be preferentially performed.
